(19) United States
(12) Patent Application Publication
(10) Pub. No.: US 2010/0164513 A1
(43) Pub. Date: Jul. 1, 2010

(54) NON-DESTRUCTIVE ON-LINE METHOD FOR MEASURING PREDETERMINED PHYSICAL, ELECTROCHEMICAL, CHEMICAL OR BIOLOGICAL STATE TRANSFORMATION OF A SUBSTANCE AND A SYSTEM THEREOF

(76) Inventor: Uri Rapoport, Moshav Ben Shemen (IL)

Correspondence Address: The Law Office of Michael E. Kondoudis, 888 16th Street, N.W., Suite 800, Washington, DC, 20006, US

(21) Appl. No.: 12/377,980

(22) PCT Filed: Aug. 21, 2007
(86) PCT No.: PCT/IL07/01043

§ 371 Date: Feb. 19, 2009

Related U.S. Application Data
(60) Provisional application No. 60/838,887, filed on Aug. 21, 2006.

(51) Int. Cl. G01R 27/04

(52) U.S. Cl. 324/633

(57) ABSTRACT

The present invention discloses a non-destructive on-line method and a system for measuring predetermined physical, electrochemical, chemical and/or biological (PPECB) state transformation of a substance. The method comprises steps selected inter alia from (a) obtaining a non-destructive resonance system (NDRS); (b) determining a resonance frequency characterizing the substance; (c) scanning at least one initial predetermined characteristic parameter around the resonance frequency, and recording the same; (d) plotting an initial 3D chart to obtain a 3D vector which identifies the value of the initial characteristic parameter; (e) providing the examined substance inside the NDRS; (f) on-line scanning at least one corresponding measured parameter around the resonance frequency, and recording the same; (g) plotting a second 3D chart to obtain a 3D vector which identifies the value of the measured parameter; (h) comparing the 3D standard initial vector to the 3D measured vector; (i) obtaining relative characteristic parameter change; and, (j) correlating between the relative characteristic parameter change and the PPECB state transformation.

### FIELD OF THE INVENTION

The present invention generally relates to a non-destructive on-line method for measuring predetermined physical, electrochemical, chemical and/or biological state transformation of a substance.

### BACKGROUND OF THE INVENTION

Traditionally, industries have relied on off-line analysis by drawing samples and conducting tests in a central laboratory using specialized analyzing equipment to measure physical properties, electrochemical properties and chemical composition. Sample testing involves complicated and expensive procedures such as sample preparation that require experienced laboratory technicians and the purchase and maintenance of costly sample handling tools.

Improved system for measuring off-line characteristics of fluids is disclosed in U.S. Pat. No. 6,401,519.

Moreover, techniques designed to monitor on-line a specific physical state are known in the art.

CN Pat. No. 1,417,588 presents an on-line water quality monitoring network system which includes an on-line monitoring instrument comprising physical parameter sensor, chemical pollutant density analyzer and in-situ flow meter.

U.S. Pat. No. 5,522,988 discloses an on-line coupled liquid and gas chromatography system with an interface capillary tube interposed between a pair of capillary chromatographic columns.

None of these prior art references disclose a system that facilitates the optimization of the production process. Also, none of the literature cited teaches in-line and on-line physical, electrochemical and/or chemical state transformation of a stream.

Also, none of the prior art teaches the measurement of a range of physical, electrochemical and/or chemical parameter using the same system.

A simple cost-effective non-invasive, on-line method for measuring and controlling at high precision physical, electrochemical and/or chemical state transformation of a substance in an industrial environment comprising; thus meets a long felt need.

### SUMMARY OF THE INVENTION

It is thus one object of the present invention to provide an efficient non-destructive on-line method for measuring predetermined physical, electrochemical, chemical and/or biological (PPECB) state transformation of a substance; comprising: (a) obtaining a non-destructive resonance system (NDRS); (b) determining a resonance frequency characterizing said substance; (c) scanning at least one initial predetermined characteristic parameter around said resonance frequency, and recording the same; (d) plotting an initial 3D chart to obtain a 3D vector which identifies the value of said initial characteristic parameter; (e) providing said examined substance inside said NDRS; wherein said substance is flowing or stationary and the measurement is continuous or batchwise; (f) on-line scanning at least one corresponding measured parameter around said resonance frequency, and recording the same; (g) plotting a second 3D chart to obtain a 3D vector which identifies the value of said measured parameter; (h) comparing said 3D standard initial vector to said 3D measured vector; (i) obtaining relative characteristic parameter change; and, (j) correlating between said relative characteristic parameter change and said PPECB state transformation.

It is also in the scope of the invention wherein the method is adapted for measuring Smith chart of a substance comprising: (a) obtaining a non-destructive resonance system (NDRS); (b) determining a resonance frequency characterizing said substance; (c) scanning said Smith chart around said predetermined resonance frequency, and recording the same; (d) plotting a first Smith Chart to obtain a 3D vector which identifies the value of said standard Smith chart; (e) on-line scanning said corresponding on-line measured Smith Chart around said resonance frequency and recording the same; (f) plotting a second smith chart to obtain a 3D vector which identifies the value of said measured smith chart; (g) comparing said first Smith standard vector to said second Smith measured vector; (h) processing said Smith vector to obtain an impedance curve as a function of said scanned frequency; (i) obtaining the relative change of the impedance curve; and, (j) correlating between said relative impedance curve and said PPECB state transformation.

It is also in the scope of the invention wherein the method comprising the step of controlling said PPECB state transformation.

It is also in the scope of the invention wherein the method is especially adapted for measuring said PPECB state transformation over a prolonged period of time along a long frequency, having random variation.

It is also in the scope of the invention wherein the method comprising the step of determining in-line and on-line PPECB state transformation of a substrate stream, especially adapted to be performed along the production line.

It is also in the scope of the invention wherein the method is useful for optimizing a production process of flowing substances.

It is also in the scope of the invention wherein the method is especially adapted for detecting presence of at least one predetermined material as well its characteristic selected from size, size distribution, particles shape, A_{w} water content or any other characteristic in said substance.

It is also in the scope of the invention wherein the method is especially adapted to be performed on a substance undergoing a physical, biological and/or chemical change.

It is also in the scope of the invention wherein the method is especially adapted for an industrial environment selected from a group including food processing industry, pharmaceutics industry, cosmetics industry, paper industry, petroleum industry, or pollution monitor industry.

It is also in the scope of the invention wherein the method is especially adapted to control viscosity of substance selected from a group including tomato puree, tomato ketchup, tomato paste, tomato sauce, tomato beverage, tomato soup, tomato concentrate, apple puree, apple paste, apple sauce, apple beverage, apple concentrate, potato puree, potato paste, potato sauce, potato beverage, potato concentrate.

It is also in the scope of the invention wherein the method is especially adapted to control water pollution by organic contaminants, inorganic contaminants such as salts.

It is also in the scope of the invention wherein the method is especially adapted to control acidity especially in pomegranate.

It is also in the scope of the invention wherein said predetermined physical, parameter is selected from a group including boiling point, refractive index, viscosity, moisture content, acidity, rheologic properties, magnetic properties; said electrochemical parameter is selected from conductivity, pH, oxygen content, permittivity permeability or dielectric constant.

It is also in the scope of the invention wherein said chemical parameter is selected from concentration and identity of the composition.

It is also in the scope of the invention wherein said biological parameter is selected from bacteria, mold, fungi, alga, virus, microorganisms or eukaryotes.

It is also in the scope of the invention wherein said substance can be in the form of liquid, gas, solid, sol-gel, super-critical solutions or any mixtures thereof.

It is also in the scope of the invention wherein said liquid is selected from a group including edible liquid, especially fruit and vegetable juice water-miscible, water-immiscible, aggregated solutions, dispersions, emulsions, solution, slurry, polymer, solid or powder or any mixtures thereof.

It is also in the scope of the invention wherein said solid is selected from a group including grain, nano-particles, fine powders or any other flowing solids.

It is also in the scope of the invention wherein the method comprising simultaneously on-line measuring a plurality of substances by plotting a plurality of charts.

It is also in the scope of the invention wherein the method is useful for performing a feedback correction by modifying the nature of the substance, selected from desiccating, adding water to said substance.

It is also in the scope of the invention wherein the method comprising the step of activating an alarm or other warning means, when the variation of the measured value from the standard is above or below a predetermined value.

It is also in the scope of the invention to provide a non-destructive resonance system for on-line measuring and controlling PPECB state transformation of a substance comprising: (a) analyzer such as a network analyzer, comprising a data collection and transmission system; (b) optionally at least one electrode; (c) a probe apparatus consisting of at least one electromagnetic coil especially solenoid, surrounding or immersed in a process line containing the substance to be analyzed.

It is also in the scope of the invention wherein said process line is selected from a group including tube, pipe or container.

It is also in the scope of the invention wherein the system is especially adapted for measuring impedance of the coil/s in proximity of a substance.

It is also in the scope of the invention wherein the system is especially adapted for measuring said PPECB state transformation over a prolonged period of time along a long frequency, having random variation.

It is also in the scope of the invention wherein said probe is configured as a coil, a wire, or a plate.

It is also in the scope of the invention wherein the system is useful for performing a wide range of physical, electrochemical chemical and/or biological measurements.

It is also in the scope of the invention to provide a combined inline and online system, useful for determining PPECB state transformation of a substrate stream, especially along a production line.

It is also in the scope of the invention wherein the system is useful for optimizing a production process of flowing substances.

It is also in the scope of the invention wherein the system is especially adapted for detecting presence of at least one predetermined material as well its characteristic selected from size, size distribution, particles shape, A_{w} water content or any other characteristic in said substance.

It is also in the scope of the invention wherein the system is especially adapted to measure and control a substance undergoing a physical, biological and/or chemical change.

It is also in the scope of the invention wherein the system is especially adapted for an industrial environment selected from a group including food processing industry, pharmaceutics industry, cosmetics industry, paper industry, petroleum industry, or pollution monitor industry.

It is also in the scope of the invention wherein the system is especially adapted to control viscosity of substance selected from a group including tomato puree, tomato ketchup, tomato paste, tomato sauce, tomato beverage, tomato soup, tomato concentrate,apple puree, apple paste, apple sauce, apple beverage, apple concentrate, potato puree, potato paste, potato sauce, potato beverage, potato concentrate.

It is also in the scope of the invention wherein the system is especially adapted to control water pollution by organic contaminants,inorganic contaminants such as salts.

It is also in the scope of the invention wherein the system is especially adapted to control acidity especially in pomegranate.

It is also in the scope of the invention wherein said solid is selected from a group including grain.

It is also in the scope of the invention wherein said predetermined physical, parameter is selected from a group including boiling point, refractive index, viscosity, moisture content, rheologic properties, magnetic properties; said electrochemical parameter is selected from conductivity, pH, oxygen content, permittivity permeability or dielectric constant.

It is also in the scope of the invention wherein said chemical parameter is selected from concentration and identity of the composition.

It is also in the scope of the invention wherein said biological parameter is selected from bacteria, mold, fungi, alga, virus, microorganisms or eukaryotes.

It is also in the scope of the invention wherein said substance can be in the form of liquid especially fruit or vegetable juice, gas, solid, sol-gel, super-critical solutions or any mixtures thereof.

It is also in the scope of the invention wherein said liquid is selected from a group including water-miscible, water-immiscible, aggregated solutions, dispersions, emulsions, solution, slurry, polymer, solid or powder or any mixtures thereof.

It is also in the scope of the invention wherein said solid is selected from a group including nano-particles, fine powders or any other flowing solids.

While the invention is susceptible to various modifications and alternative forms, specific embodiments thereof have been shown by way of example in the drawings and will herein be described in detail. It should be understood, however, that it is not intended to limit the invention to the particular forms disclosed, but on the contrary, the intention is to cover all modifications, equivalents, and alternatives falling within the spirit and scope of the invention as defined by the appended claims.

### BRIEF DESCRIPTION OF THE FIGURES

In order to understand the invention and to see how it may be implemented in practice, and by way of non-limiting example only, with reference to the accompanying drawing, in which

FIG. 1a represents three different measure of the impedance of tomato puree around the resonance frequency;

FIG. 1b represents three different relative measures of the same;

FIG. 2a represents three different measure of the inductance of tomato puree around the resonance frequency;

FIG. 2b represents three relative different measures of the same; and,

FIG. 3 schematically represents a probe apparatus according to one embodiment of the present invention.

FIG. 4 schematically represents in a flow diagram the method for measuring predetermined physical, electrochemical, chemical or biological state transformation of a substance.

### DETAILED DESCRIPTION OF PREFERRED EMBODIMENTS

The following description is provided, alongside all chapters of the present invention, so as to enable any person skilled in the art to make use of said invention and sets forth the best modes contemplated by the inventor of carrying out this invention. Various modifications, however, will remain apparent to those skilled in the art, since the generic principles of the present invention have been defined specifically to provide a non-invasive, on-line method for measuring and controlling at high precision physical, electrochemical and/or chemical state transformation of a substance in an industrial environment.

The term ‘on-line’ refers in the present invention to the operational measuring performance of the system available for immediate use avoiding human intervention.

The term ‘in-line’ refers in the present invention to the monitoring being an integral part of a successive sequence of operations or machines during manufacturing process.

The term ‘biological change’ or ‘chemical change’ refers in the present invention to any enzymatic, hormonal, pathological, microbiological such as biocide, ripping change, oxidation state, reduction state, pH, concentration changes of soluble or otherwise dispersed compositions, water activity, etc.

The term ‘state transformation’ refers in the present invention to any physical, electrochemical, chemical and/or biological state transformations and changes, including biological changes and chemical changes.

The term ‘plurality’ applies hereinafter to any integer greater than or equal to one.

The term ‘Smith Chart’ refers in the present invention to a type of chart used to plot variances of complex transmission impedance along its length. Smith chart denotes to a representation of a sequence of normalized impedance, admittance or reflection coefficient in a circle of unity radius. The Smith chart is plotted in two dimensions and is scaled in normalised impedance (the most common), normalised admittance or both, using different colours to distinguish between them. These are often known as the Z, Y and YZ Smith Charts respectively. Normalised scaling allows the Smith Chart to be used for problems involving any characteristic impedance or system impedance The Smith chart contains almost all possible impedances, real or imaginary, within one circle. With relatively simple graphical construction it is straightforward to convert between normalised impedance (or normalised admittance) and the corresponding complex voltage reflection coefficient.

The purpose of the Smith chart is to identify all possible impedances on the domain of existence of the reflection coefficient. The normalized impedance is represented on the Smith chart by using families of curves that identify the normalized resistance R (real part) and the normalized reactance X (imaginary part).

The term “impedance (Z)” refers hereinafter to a term that describes a measure of opposition to a sinusoidal alternating current. Electrical impedance extends the concept of resistance to AC circuits, describing not only the relative magnitudes of the voltage and current, but also the relative phases. Impedance refers to the steady state AC term for the combined effect of both resistance (R) and reactance (X), where Z=R+jX. (X=jwL for an inductor, and X=1/jwC for a capacitor, where w is the radian frequency or 2*pi*f.) Generally, Z is a complex quantity having a real part (resistance) and an imaginary part (reactance).

The term “admittance (Y)” refers hereinafter to the inverse of the impedance (Z). The term “admittance” combines the effect of both conductance (G) and susceptance (B).

The term “susceptance (B)” refers hereinafter to the imaginary part of the admittance.

It is according to a further embodiment of the current invention to present a method comprising the step of or the steps of determining in-line and on-line physical, electrochemical, chemical and/or biological state transformation of a substrate stream, especially adapted to be performed along the production line and hence avoiding slowing down the manufacturing process.

It is according to a further embodiment of the current invention to present a method especially adapted for detecting presence i.e. the concentration and the identification of at least one predetermined material as well its characteristic selected from size, size distribution, particles shape, a_{w}, water content, in said substance.

A measuring probe equipped with an analyzer was calibrated and adjusted to a resonance frequency for a given solution. A smith chart was measured and the measurement on the resonant frequency was recorded.

It is according to a further embodiment of the current invention to present a network analyser or any other means, of analyzing variations in the on-line measured parameter, such as the impedance of the probe, or the variation in the load on the coil.

The system is applied to the measurement of physical, electrochemical and/or chemical state transformation through the use in the vicinity of a coil which produces a change in for example impedance of the probe. The present system enables precise measurement of the relative changes in the conductivity, dielectric constant or magnetic properties of the substance.

Moreover, the present system enables correlation between the measured value and the identification of the chemical composition change. Each different composition has a different response. Scanning through a number of frequencies identifies a chemical; a resultant response has a vector which precisely identifies the chemical.

It is also an object of the invention to use the resonance system of the present invention to detect the presence of a specific material in a fluid. The fluid composition itself can be any type of fluid, such as a solution, a liquid containing suspended particulates, or, in some embodiments, even a gas phase containing a particular chemical or a mixture of chemicals. It can also include a liquid composition undergoing a physical and/or chemical change.

The analyzer determines the difference between the value of the smith chart as measured by the measuring device and the value as stored in the standard database. The difference between the two values is correlated to the physical/chemical properties which determine the chemical/physical in-line state of the stream depending on the particular application.

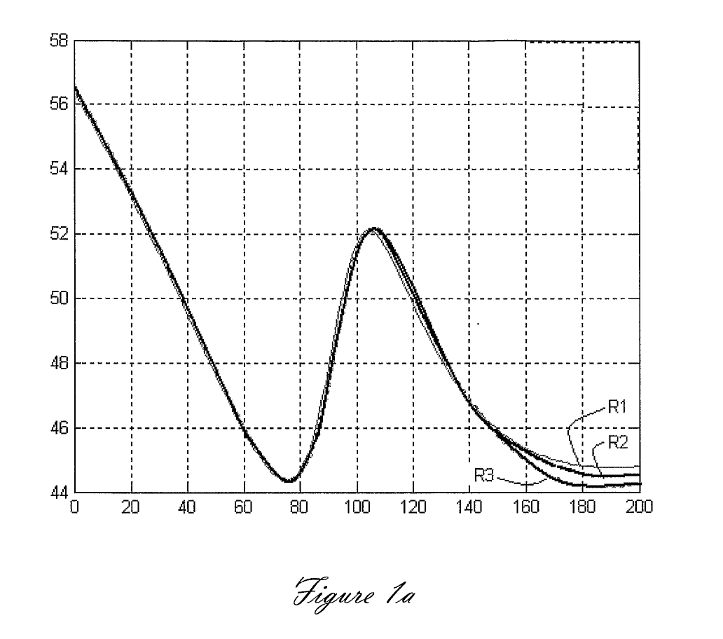

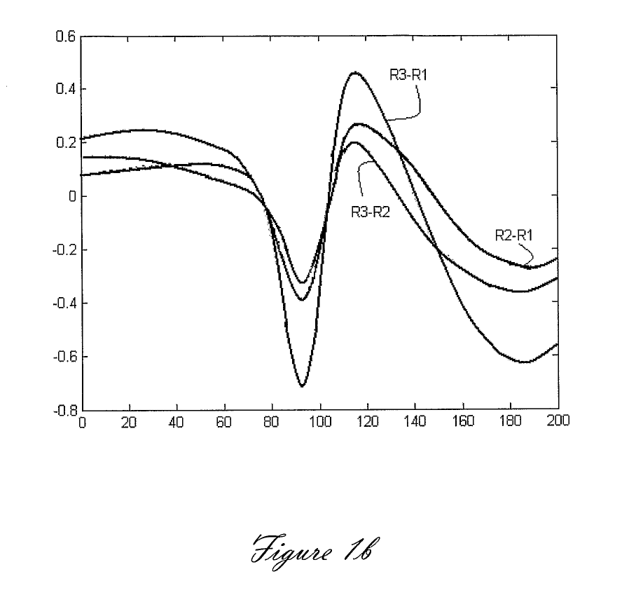

Reference is now made to FIG. 1a, presenting three different measures of an impedance of tomato puree, namely R1, R2 and R3, processed from a Smith Chart, recorded around pick of resonance frequency (e.g., 100 MHz) according to one embodiment of the present invention.

Reference is now made to FIG. 1b, presenting three different relative measures of the same, namely R2-R1, R3-R1; R3-R2.

If the obtained value of R3-R2 is correlated with the standard desired viscosity of the tomato puree, then, the R2-R1 characterizes the diluted feature of the tomato puree and R3-R1 characterizes the further diluted feature of the tomato puree in comparison to the standard.

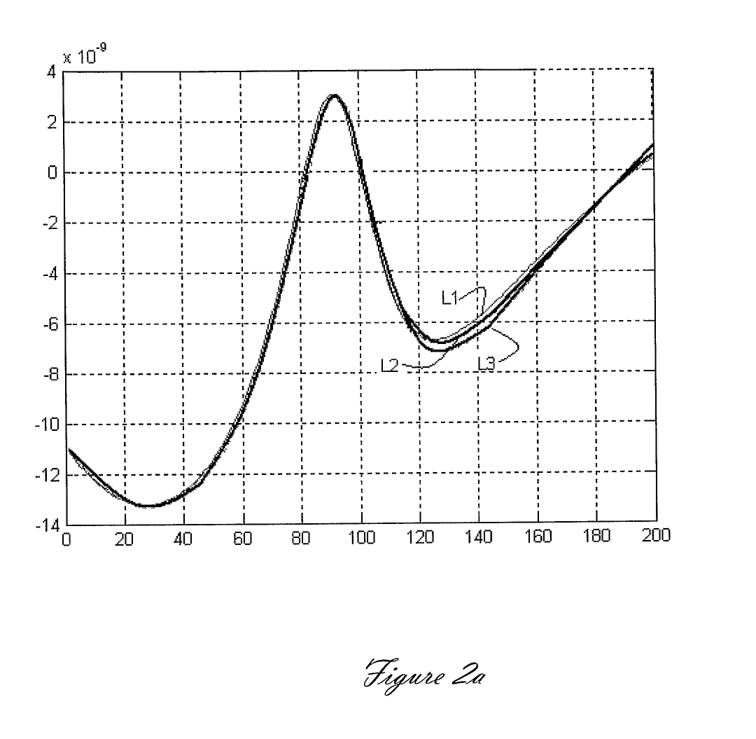

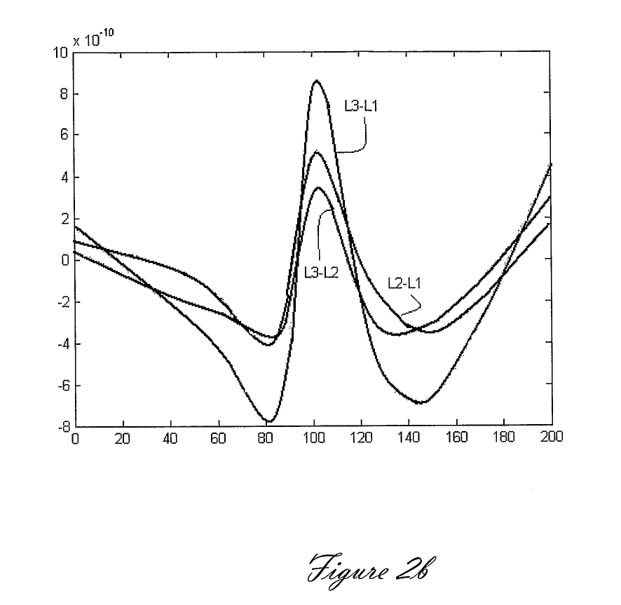

Reference is now made to FIG. 2a, presenting a schematic illustration of the three different measure of the inductance of tomato puree, namely L1, L2 and L3, around the resonance frequency.

Reference is now made to FIG. 2b, presenting a schematic illustration of the three relative different measures of the same, same namely L2-L1, L3-L1; L3-L2.

If the L3-L2 value is correlated with the standard desired viscosity of the tomato puree, the L2-L1 characterizes the diluted feature of the tomato puree and L3-L1 characterizes the further diluted feature of the tomato puree in comparison to the standard.

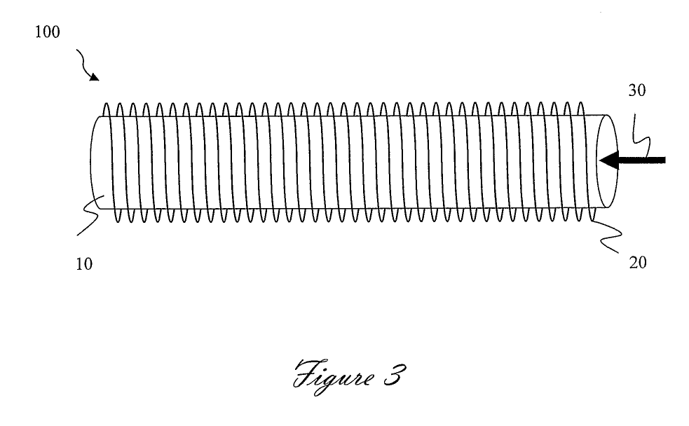

Reference is made now to FIG. 3, schematically presenting a probe apparatus 100 showing process line 10 such as a pipe, a probe 20 formed as a loop or series of loops, and direction of fluid flow 30.

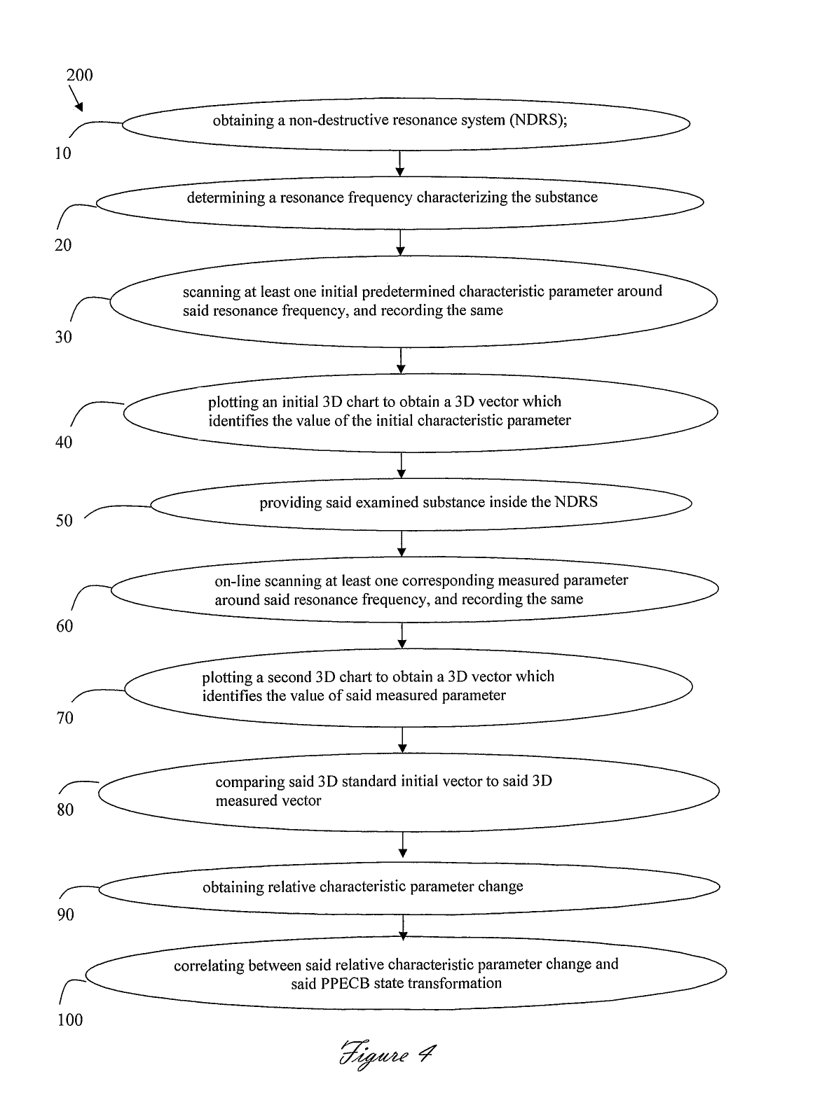

Reference is made now to FIG. 4 which represents in a flow diagram the method (200) for measuring predetermined physical, electrochemical, chemical or biological state transformation of a substance. At the first stage (10) a resonance system (NDRS) is obtained. Next (20) a resonance frequency characterizing the substance is determined. At the next step (30) at least one initial predetermined characteristic parameter around the resonance frequency is scanned and recorded. At the next step (40) an initial 3D chart to obtain a 3D vector which identifies the value of the initial characteristic parameter is plotted. Next, (50) the examined substance is provided in the NDRS. At the next step (60), at least one corresponding measured parameter around the resonance frequency is on-line scanned and recorded. At the next step (70), a second 3D chart to obtain a 3D vector which identifies the value of the measured parameter is plotted. Next, (80) comparing the 3D standard initial vector to the 3D measured vector. Next, (90) relative characteristic parameter change is obtained. At the last step (100) the relative characteristic parameter change and the PPECB state transformation are correlated.

### Examples

Various examples were carried out to prove the embodiments claimed in the present invention. Some of these experiments are referred hereinafter. The examples describe the manner and process of the present invention and set forth the best mode contemplated by the inventors for carrying out the invention, but are not to be construed as limiting the invention.

### Example 1

The water salinity can be used for homeland security in the event of a spilling a poison, contaminant or chemical. While most of the existing detection technologies can detect contaminants at very low concentrations, they are often specific to one contaminant or a group of contaminants. Because the physical and chemical properties of potential contaminants can vary greatly, instruments that measure one contaminant or a small subset of possible contaminants is of little use because that contaminant may not be the one used. Most of the biological monitors, such as the use of algae, had limited distribution system. Monitors that use fish or mussels can detect cyanide and chlorinated pesticides, but not at the desired detection limit.

A measuring probe equipped with an analyzer is placed on water well and is calibrated and adjusted to a resonance frequency for a given potable water solution such that a reference is created. A smith chart was measured and the measurement on the resonant frequency was recorded. If any additional substance is added to the water, the load on the coil will vary. Each different composition has a different response. On-line measure of the load on the coil around the resonance frequency is continuously performed on the water stream performing water quality monitoring. The variation of the measured value from the standard one enables detection of the water composition change. An alert is activated if the system detects a predetermined significant change.

### Example 2

A measuring probe equipped with an analyzer is placed on a ketchup production line and is calibrated and adjusted to a resonance frequency for a given ketchup viscosity. A smith chart was measured and the measurement on the resonant frequency was recorded. On-line and in-line measure of the smith chart around the resonance frequency is continuously performed on the ketchup stream. On line information e.g. water quantity or water activity Aw is available in the control room enabling either automatically or manually immediate response. An alert may be activated if the system detects a predetermined significant change having precision of about 0.5%, in order to lower or to higher the water quantity on-line and in-line, such that a predetermined standard viscosity according to the customer requirements and preferences is obtained.

### Example 3

A measuring probe equipped with an analyzer is placed on a apple puree production line and is calibrated and adjusted to a resonance frequency for a given apple puree viscosity. A smith chart was measured and the measurement on the resonant frequency was recorded. On-line and in-line measure of the smith chart around the resonance frequency is continuously performed on the apple puree stream. An alert is activated if the system detects a predetermined significant change having precision of about 0.5%, in order to lower or to higher the water quantity on-line and in-line, such that a predetermined standard viscosity according to customer desire is obtained.

### Example 4

The chemical industry in particular prefers to minimize human exposure to chemicals for safety reasons and to avoid human error. The system determines the correlating changes in concentration of particular chemicals (e.g., such as hydrogen peroxide concentration) in the chemical transport conduit, to smith chart measurement. The analyzer performs a linear correlation between the smith chart measurement and the percentage of a particular chemical, e.g., hydrogen peroxide, glycol, and the like, in the process chemical or slurry in the chemical transport conduit. The measurement of the chemical transport conduit may be performed on a portion of the chemical transport conduit (e.g., a slip stream).

### Example 5

The system also provides an automated and non-invasive on-line and in line monitoring of chemical reactions, such as NaOH+Cl2→NaOCl+HCl. A smith chart is measured and the measurement on the resonant frequency is recorded.

### Example 6

The system also provides an automated and non-invasive monitoring on grain stream. The information of the grain monitoring is used to establish the quality characteristics and the value of the grain. The monitoring is also necessary for proper grain storage management. Information from the grain, such as grain moisture content and the amount of foreign material, can be used to determine appropriate action to maintain the quality of the stored product. The distribution of constituents is generally not uniform throughout the load; the constituents of the grain mass stratify and segregate. This causes variations in the physical characteristics within the load. The air space between the grain constituents cause leaps in the measurement. The method of monitoring is therefore extremely important to ensure that the grain stream is truly representative of the whole grain mass. The frequency per unit volume of grain is measured. A smith chart is of measured and the measurement on the resonant frequency is recorded. The information about the obtained grain moisture is the average moisture of the whole grain mass.

1. A non-destructive on-line method for measuring predetermined physical, electrochemical, chemical and/or biological (PPECB) state transformation of a substance; comprising:
a. obtaining a non-destructive resonance system (NDRS);
b. determining a resonance frequency characterizing said substance;
c. scanning at least one initial predetermined characteristic parameter around said resonance frequency, and recording the same;
d. plotting an initial 3D chart to obtain a 3D vector which identifies the value of said initial characteristic parameter;
e. providing said examined substance inside said NDRS;
f. on-line scanning at least one corresponding measured parameter around said resonance frequency, and recording the same;
g. plotting a second 3D chart to obtain a 3D vector which identifies the value of said measured parameter;
h. comparing said 3D standard initial vector to said 3D measured vector;
i. obtaining relative characteristic parameter change; and,
j. correlating between said relative characteristic parameter change and said PPECB state transformation.

2. The method according to claim 1, adapted for measuring Smith chart of a substance comprising:
a. obtaining a non-destructive resonance system (NDRS);
b. determining a resonance frequency characterizing said substance;
c. scanning said Smith chart around said predetermined resonance frequency, and recording the same;
d. plotting a first Smith Chart to obtain a 3D vector which identifies the value of said standard Smith chart;
e. on-line scanning said corresponding on-line measured Smith Chart around said resonance frequency and recording the same;
f. plotting a second smith chart to obtain a 3D vector which identifies the value of said measured smith chart;
g. comparing said first Smith standard vector to said second Smith measured vector;
h. processing said Smith vector to obtain an impedance curve as a function of said scanned frequency;
i. obtaining the relative change of the impedance curve; and,
j. correlating between said relative impedance curve and said PPECB state transformation.

3. The method according to claim 1, additionally comprising the step of controlling said PPECB state transformation.

4. The method according to claim 1, especially adapted for measuring said PPECB state transformation over a prolonged period of time along a long frequency, having random variation.

5. The method according to claim 1, additionally comprising the step of determining in-line and on-line PPECB state transformation of a substrate stream, especially adapted to be performed along the production line.

6. The method according to claim 1, useful for optimizing a production process of flowing substances.

7. The method according to claim 1, especially adapted for detecting presence of at least one predetermined material as well its characteristic selected from size, size distribution, particles shape, A_{w} water content or any other characteristic in said substance.

8. The method according to claim 1, especially adapted to be performed on a substance undergoing a physical, biological and/or chemical change.

9. The method according to claim 1, especially adapted for an industrial environment selected from a group including food processing industry, pharmaceutics industry, cosmetics industry, paper industry, petroleum industry, or pollution monitor industry.

10. The method according to claim 1, especially adapted to control viscosity of substance selected from a group including tomato puree, tomato ketchup, tomato paste, tomato sauce, tomato beverage, tomato soup, tomato concentrate, apple puree, apple paste, apple sauce, apple beverage, apple concentrate, potato puree, potato paste, potato sauce, potato beverage, potato concentrate.

11. The method according to claim 1 especially adapted to control water pollution by organic contaminants, inorganic contaminants such as salts.

12. The method according to claim 1, especially adapted to control acidity especially in pomegranate.

13. The method according to claim 1, wherein said predetermined physical, parameter is selected from a group including boiling point, refractive index, viscosity, moisture content, acidity, rheologic properties, magnetic properties; said electrochemical parameter is selected from conductivity, pH, oxygen content, permittivity permeability or dielectric constant.

14. The method according to claim 1, wherein said chemical parameter is selected from concentration and identity of the composition.

15. The method according to claim 1, wherein said biological parameter is selected from bacteria, mold, fungi, alga, virus, microorganisms or eukaryotes.

16. The method according to claim 1, wherein said substance can be in the form of liquid, gas, solid, sol-gel, super-critical solutions or any mixtures thereof.

17. The method according to claim 16, wherein said liquid is selected from a group including edible liquid, especially fruit, vegetable juice, water-miscible, water-immiscible, aggregated solutions, dispersions, emulsions, solution, slurry, polymer, solid or powder or any mixtures thereof.

18. The method according to claim 16, wherein said solid is selected from a group including grain, nano-particles, fine powders or any other flowing solids.

19. The method according to claim 1, additionally comprising simultaneously on-line measuring a plurality of substances by plotting a plurality of charts.

20. A feedbacked method according to claim 1, useful for performing a feedback correction by modifying the nature of the substance, selected from desiccating, adding water to said substance.

21. A feedback method according to claim 1, additionally comprising the step of activating an alarm or other warning means, when the variation of the measured value from the standard is above or below a predetermined value.

22. A non-destructive resonance system (NDRS) for on-line measuring and controlling PPECB state transformation of a substance comprising:
a. analyzer especially a network analyzer, comprising means for data collection and transmission;
b. optionally at least one electrode; and,
c. a probe apparatus comprising at least one electromagnetic coil, especially solenoid, surrounding or immersed in a process line containing the substance to be analyzed.

23. The system according to claim 22, wherein said process line is selected from a group including tube, pipe or container.

24. The system according to claim 22, especially adapted for measuring impedance of the coil/s in proximity of a substance.

25. The system according to claim 22, especially adapted for measuring said PPECB state transformation over a prolonged period of time along a long frequency, having random variation.

26. The system according to claim 22, wherein said probe is configured as a coil, a wire, or a plate.

27. The system according to claim 22, useful for performing a wide range of physical, electrochemical chemical and/or biological measurements.

28. A combined inline and online system according to claim 22, useful for determining PPECB state transformation of a substrate stream, especially along a production line.

29. The system according to claim 22, useful for optimizing a production process of flowing substances.

30. The system according to claim 22, especially adapted for detecting presence of at least one predetermined material as well its characteristic selected from size, size distribution, particles shape, A_{w} water content or any other characteristic in said substance.

31. The system according to claim 22, especially adapted to measure and control a substance undergoing a physical, biological and/or chemical change.

32. The system according to claim 22, especially adapted for an industrial environment selected from a group including food processing industry, pharmaceutics industry, cosmetics industry, paper industry, petroleum industry, or pollution monitor industry.

33. The system according to claim 22, especially adapted to control viscosity of substance selected from a group including tomato puree, tomato ketchup, tomato paste, tomato sauce, tomato beverage, tomato soup, tomato concentrate, apple puree, apple paste, apple sauce, apple beverage, apple concentrate, potato puree, potato paste, potato sauce, potato beverage, potato concentrate.

34. The system according to claim 22, especially adapted to measure and control water pollution by organic contaminants and inorganic contaminants such as salts.

35. The system according to claim 22, especially adapted to measure and acidity especially in pomegranate.

36. The system according to claim 22, wherein said solid is selected from a group including grain.

37. The system according to claim 22, wherein said predetermined physical, parameter is selected from a group including boiling point, refractive index, viscosity, moisture content, rheologic properties, magnetic properties; said electrochemical parameter is selected from conductivity, pH, oxygen content, permittivity permeability or dielectric constant.

38. The system according to claim 22, wherein said chemical parameter is selected from concentration and identity of the composition.

39. The system according to claim 22, wherein said biological parameter is selected from bacteria, mold, fungi, alga, virus, microorganisms or eukaryotes.

40. The system according to claim 22, wherein said substance can be in the form of liquid especially fruit or vegetable juice, gas, solid, sol-gel, super-critical solutions or any mixtures thereof.

41. The system according to claim 40, wherein said liquid is selected from a group including water-miscible, water-immiscible, aggregated solutions, dispersions, emulsions, solution, slurry, polymer, solid or powder or any mixtures thereof.

42. The system according to claim 40, wherein said solid is selected from a group including nano-particles, fine powders or any other flowing solids.
